(19) United States
(12) Patent Application Publication
(10) Pub. No.: US 2025/0331424 A1
(43) Pub. Date: Oct. 23, 2025

(54) SEMICONDUCTOR PACKAGES WITH THERMAL STRUCTURES

(71) Applicant: Taiwan Semiconductor Manufacturing Co., Ltd., Hsinchu (TW)

(72) Inventors: Chen-Yen Hung, Taichung City (TW); Chien-Yuan Huang, Hsinchu (TW); Shih-Chang Ku, Taipei City (TW)

(21) Appl. No.: 19/258,518

(22) Filed: Jul. 2, 2025

Related U.S. Application Data
(63) Continuation of application No. 18/610,668, filed on Mar. 20, 2024.
(60) Provisional application No. 63/614,698, filed on Dec. 26, 2023.

(51) Int. Cl. H10N 19/00; H01L 21/56; H01L 23/00; H01L 23/38; H01L 25/00; H01L 25/065; H10N 10/01; H10N 10/10

(52) U.S. Cl. CPC H10N 19/00; H01L 21/56; H01L 23/38; H01L 25/0655; H01L 25/50; H10N 10/01; H10N 10/10; H01L 24/16; H01L 24/32; H01L 24/73; H01L 2224/16225; H01L 2224/32225; H01L 2224/73204

(57) ABSTRACT

A method includes forming a first thermoelectric component on a first die; forming a second thermoelectric component on a second die; and connecting the first die and the second die to an interposer, wherein connecting the first die and the second die to the interposer electrically couples the first thermoelectric component and the second thermoelectric component to the interposer.

### PRIORITY CLAIM AND CROSS-REFERENCE

This application is a continuation of U.S. patent application Ser. No. 18/610,668, filed on Mar. 20, 2024, which claims the benefit of U.S. Provisional Application No. 63/614,698, filed on Dec. 26, 2023, each application is hereby incorporated herein by reference.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed. For example, one problem of concern is the dissipation of heat.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, and 8 illustrate intermediate steps in the formation of a thermoelectric component, in accordance with some embodiments.

FIGS. 9, 10, 11, 12, and 13 illustrate intermediate steps in the formation of a package component, in accordance with some embodiments.

FIGS. 14 and 15 illustrate intermediate steps in the formation of a package, in accordance with some embodiments.

FIG. 16 illustrates a thermoelectric component, in accordance with some embodiments.

FIGS. 17 and 18 illustrate intermediate steps in the formation of a device, in accordance with some embodiments.

FIG. 19 illustrates a package component, in accordance with some embodiments.

FIG. 20 illustrates a package, in accordance with some embodiments.

FIG. 21 illustrates a package component, in accordance with some embodiments.

FIGS. 22 and 23 illustrate intermediate steps in the formation of a package component, in accordance with some embodiments.

FIG. 24 illustrates a package, in accordance with some embodiments.

FIG. 25 illustrates a schematic plan view of a package component, in accordance with some embodiments.

FIG. 26 illustrates a schematic plan view of a package component, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments of the present disclosure, thermoelectric (TE) components are bonded or attached to dies to form package components. The TE components may be utilized as thermoelectric generators (TEG) to generate electrical power from the waste heat of high-power dies and provide power to other TE components operated as thermoelectric coolers (TEC). In this manner, the electrical power generated from the heat dissipation of high-power packages is utilized to facilitate the heat dissipation of low-power packages, and the energy used for heat dissipation within a package may be reduced. Additionally, the thermal stability and temperature control of a package may be improved.

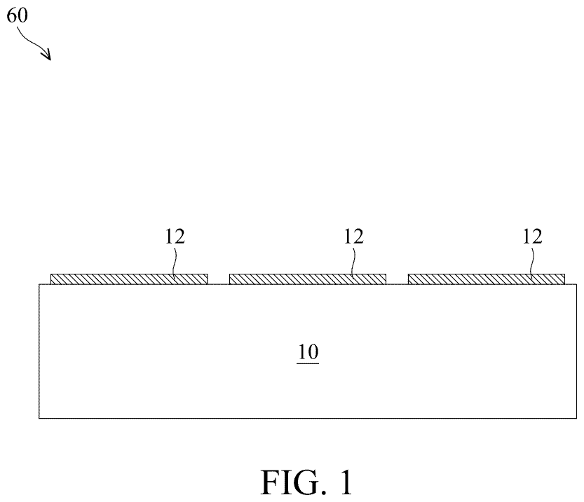

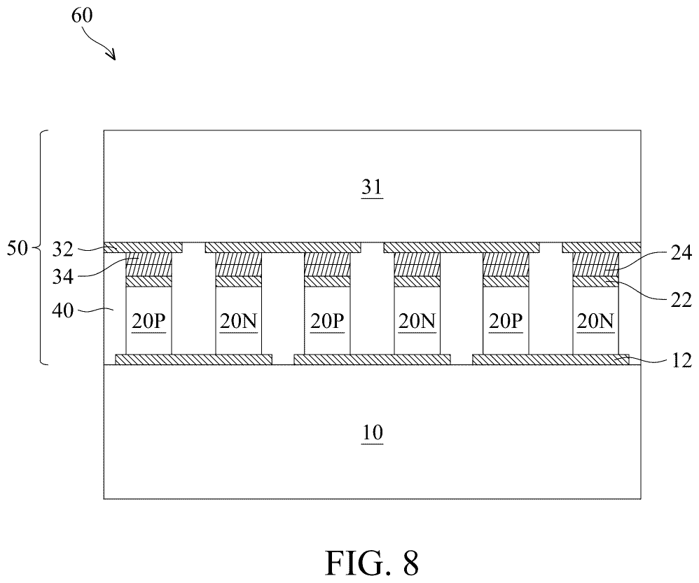

FIGS. 1 through 8 illustrate cross-sectional views of intermediate steps in the formation of a device 60 comprising a thermoelectric (TE) component 50 integrated with a structure 10, in accordance with some embodiments. The TE component 50 (see FIG. 8) may be operated as a thermoelectric generator (TEG) and/or as a thermoelectric cooler (TEC), in some embodiments. For example, when operated as a TEG, a heat difference between opposite sides of the TE component 50 allows the TE component 50 to generate electrical power (e.g., by the Seebeck effect). In this manner, a TE component 50 formed on a structure 10 may be able to generate electrical power based on heat generated by the structure 10. When operated as a TEC, an electrical current flowing through the TE component 50 allows the TE component 50 to transfer heat from one side of the TE component 50 to the opposite side of the TE component 50 (e.g., by the Peltier effect). In this manner, a TE component 50 formed on a structure 10 may be able to provide cooling for the structure 10 by transferring heat away from the structure 10. In a similar manner, a TE component 50 may be able to heat the structure 10 by transferring heat towards the structure 10. In some embodiments, the structure 10 may be a die, a chip, a package, a component, or the like. A TE component 50 may be operated exclusively as a TEG, may be operated exclusively as a TEC, or may be configured to switch between TEG operation and TEC operation. Switching a TE component 50 between TEG operation and TEC operation can allow for increased flexibility and efficiency of thermal management. One TE component 50 or multiple TE components 50 may be formed on the same structure 10. The TE components 50 shown in the figures are intended as examples, and the TE components 50 used in any of the embodiments herein may be different from the TE components 50 illustrated in the figures. Accordingly, all suitable variations of TE components 50 are within the scope of the present disclosure.

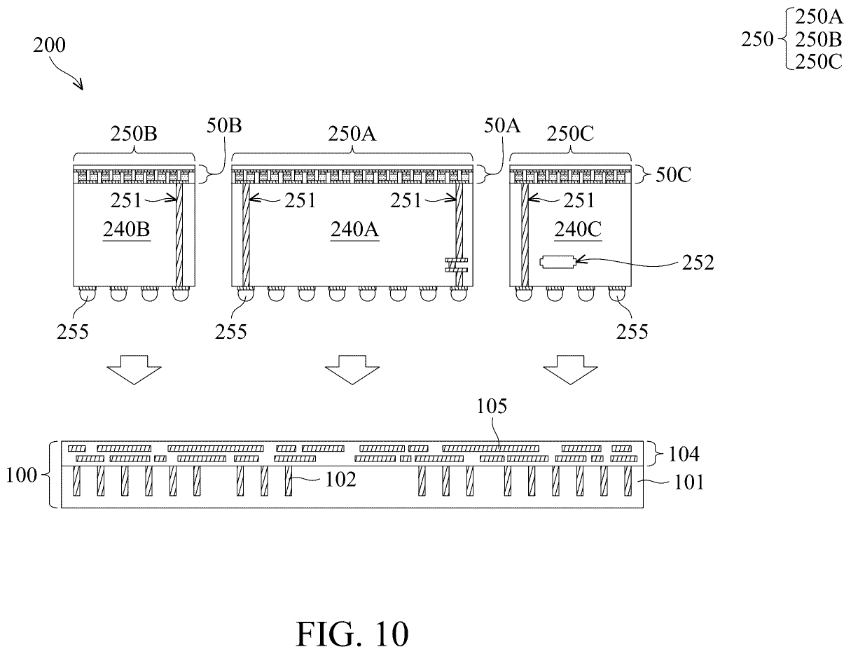

FIG. 1 illustrates the formation of a bottom metallization pattern 12 on a structure 10, in accordance with some embodiments. The structure 10 may be any suitable structure, such as a package, a package component, a semiconductor device, an integrated circuit die, a chip, a module, or the like. For example, in some embodiments, the structure 10 may be a die 240, described below for FIG. 10.

The bottom metallization pattern 12 may comprise conductive pads, conductive lines, conductive routing, or the like that is subsequently used to form electrical connections between n-type regions 20N and p-type regions 20P of the TE component 50, described in greater detail below. As an example to form the bottom metallization pattern 12, a seed layer is formed over the structure 10. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. A photoresist (not shown) is then formed and patterned on the seed layer. The photoresist may be formed by spin coating or the like and may be exposed to light for patterning. The pattern of the photoresist corresponds to the bottom metallization pattern 12. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the bottom metallization pattern 12.

The above is one example for forming the bottom metallization pattern 12, but the bottom metallization pattern 12 may be formed using any suitable techniques. As another example, the bottom metallization pattern 12 may be formed by depositing one or more metal layers on the structure 10 and then patterning the one or more metal layers using suitable photolithography and etching techniques. In some embodiments, the bottom metallization pattern 12 may include a liner, such as a barrier layer or the like.

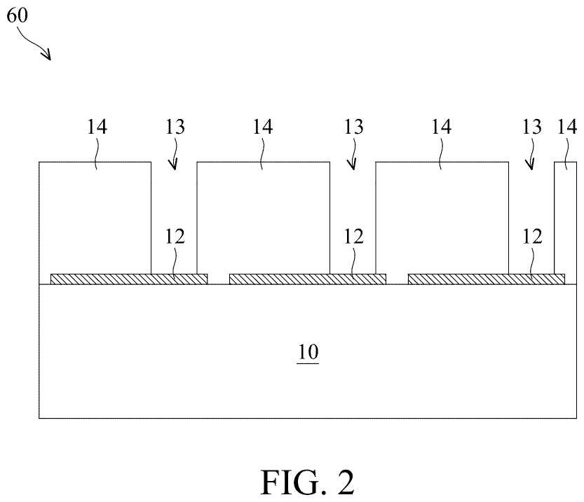

In FIG. 2, a patterned mask 14 is formed that exposes the bottom metallization pattern 12, in accordance with some embodiments. For example, the patterned mask 14 may be formed by depositing a photoresist over the bottom metallization pattern 12 and the structure 10. The photoresist may be deposited using a spin-on technique or the like. The photoresist is then patterned to form openings 13 that expose portions of the bottom metallization pattern 12. The photoresist can be patterned using suitable photolithography techniques. Other patterned masks 14 or formation techniques are possible.

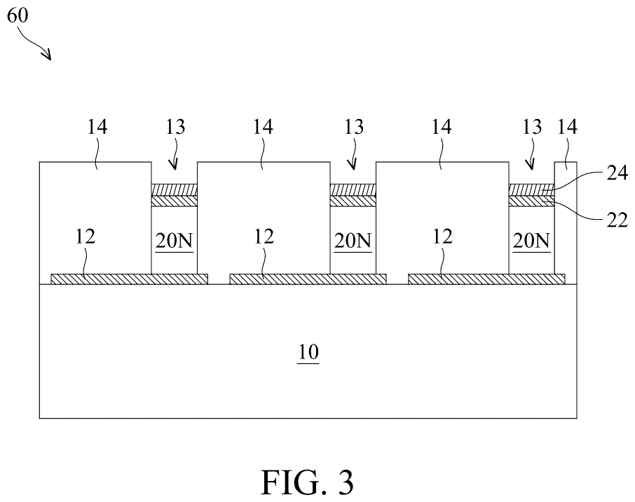

In FIG. 3, n-type regions 20N, conductive layer 22, and bond regions 24 are formed, in accordance with some embodiments. The n-type regions 20N are formed on and make electrical contact to the portions of the bottom metallization pattern 12 that are exposed by the openings 13. The n-type regions 20N comprise a suitable thermoelectric material, which may be doped with one or more n-type dopants. For example, the n-type regions 20N may comprise BiₓTe_{y}, BiₓSb_{y}Te_{z}, BiₓSe_{y}Te_{z}, or the like, which may be doped with suitable n-type dopants. In other embodiments, the n-type regions 20N may be undoped. The n-type regions 20N may be deposited using a suitable technique, such as sputtering, electrochemical deposition, CVD, PVD, or the like. The n-type regions 20N may be formed having a thickness in the range of about 5 μm to about 25 μm, though other thicknesses are possible.

A conductive layer 22 is then deposited on the n-type regions 20N within the openings 13, in accordance with some embodiments. The conductive layer 22 provides electrical connection to the n-type regions 20 and facilitates adhesion of the overlying bond regions 24 (described below). The conductive layer 22 may comprise one or more metals, such as copper, titanium, tungsten, aluminum, indium, alloys thereof, or the like, and may be deposited using suitable techniques such as plating, CVD, PVD, ALD, or the like. The conductive layer 22 may or may not be formed of a material similar to that of the metallization pattern 12.

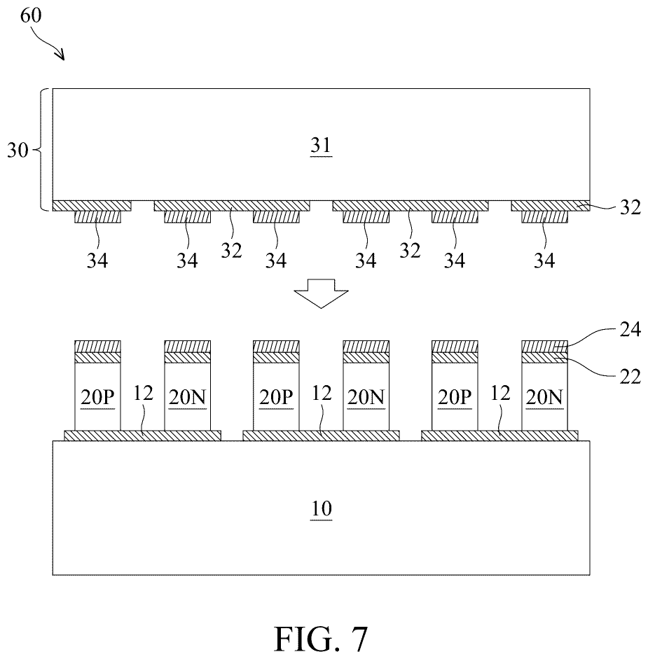

The bond regions 24 are then formed on the conductive layer 22, in accordance with some embodiments. A bond region 24 is formed on the conductive layer 22 within each opening 13. The bond regions 24 are subsequently bonded to corresponding bond regions 34 of a metallization component 30 (see FIGS. 7-8). The bond regions 24 may be formed of one or more metal layers formed using suitable techniques. For example, in some embodiments, the bond regions 24 comprise a layer of indium formed using a suitable technique such as sputtering, evaporation, plating, CVD, PVD, ALD, or the like. Other materials or deposition techniques are possible. After depositing the bond regions 24, the patterned mask 14 is removed using a suitable process, such as an ashing process or the like.

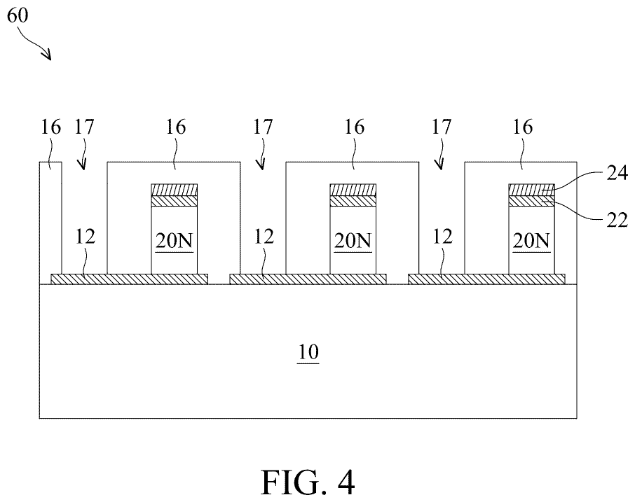

In FIG. 4, a patterned mask 16 is formed that exposes the bottom metallization pattern 12, in accordance with some embodiments. For example, the patterned mask 16 may be formed by depositing a photoresist over the bottom metallization pattern 12, the structure 10, the n-type regions 20N, the conductive layer 22, and the bond regions 24. The photoresist may be deposited using a spin-on technique or the like. The photoresist is then patterned to form openings 17 that expose portions of the bottom metallization pattern 12. The portions of the bottom metallization pattern 12 exposed by the openings 17 may be separate from but adjacent to the n-type regions 20N. The photoresist can be patterned using suitable photolithography techniques. Other patterned masks 16 or formation techniques are possible.

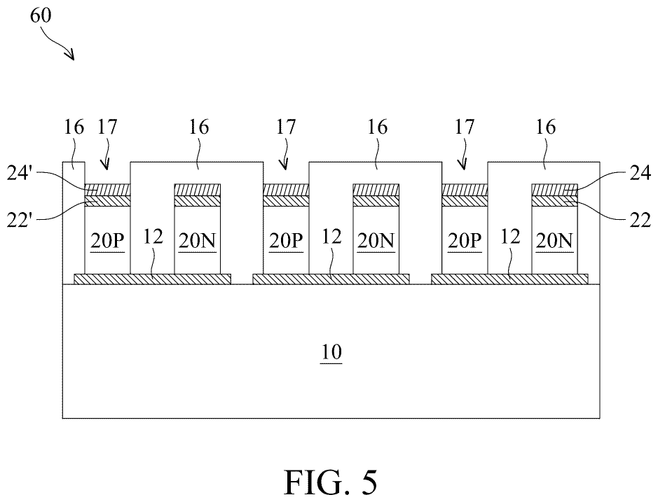

In FIG. 5, p-type regions 20P, conductive layer 22′, and bond regions 24′ are formed, in accordance with some embodiments. The p-type regions 20P are formed on and make electrical contact to the portions of the bottom metallization pattern 12 that are exposed by the openings 17. The p-type regions 20P comprise a suitable thermoelectric material, which may be doped with one or more p-type dopants. For example, the p-type regions 20P may comprise BiₓTe_{y}, BiₓSb_{y}Te_{z}, BiₓSe_{y}Te_{z}, or the like, which may be doped with suitable p-type dopants. In other embodiments, the p-type regions 20P may be undoped. The p-type regions 20P may comprise a material similar to the n-type regions 20N, in some embodiments. The p-type regions 20P may be deposited using a suitable technique, such as sputtering, electrochemical deposition, CVD, PVD, or the like. The p-type regions 20P may be formed having a thickness in the range of about 5 μm to about 25 μm, which may be similar to the thickness of the n-type regions 20N, though other thicknesses are possible. In this manner, the TE component 50 comprises alternating regions of an n-type material 20N and a p-type material 20P, in some embodiments. In some embodiments, the metallization pattern 12 electrically connects corresponding pairs of n-type regions 20N and p-type regions 20P, as shown in FIG. 5.

A conductive layer 22′ is then deposited on the p-type regions 20P within the openings 17, in accordance with some embodiments. The conductive layer 22′ may be similar to the conductive layer 22 described previously, and may be formed of similar materials using similar deposition techniques. In other embodiments, the conductive layer 22′ deposited on the p-type regions 20P comprises a different material than the conductive layer 22 deposited on the n-type regions 20N. For simplicity, the conductive layer 22′ and the conductive layer 22 may collectively be referred to as the conductive layer 22 in subsequent figures and their descriptions. In other embodiments, the conductive layer 22 is formed over both the n-type regions 20N and the p-type regions 20P using the same deposition step.

The bond regions 24′ are then formed on the conductive layer 22′, in accordance with some embodiments. The bond regions 24′ may be similar to the bond regions 24 described previously, and may be formed of similar materials using similar deposition techniques. For example, in some embodiments, the bond regions 24′ comprise indium formed using a suitable technique. In other embodiments, the bond regions 24′ deposited on the conductive layer 22′ comprises a different material than the bond regions 24 deposited on the conductive layer 22. For simplicity, the bond regions 24′ and the bond regions 24 may collectively be referred to as the bond regions 24 in subsequent figures and their descriptions. In other embodiments, the bond regions 24 are formed over both the n-type regions 20N and the p-type regions 20P using the same deposition step.

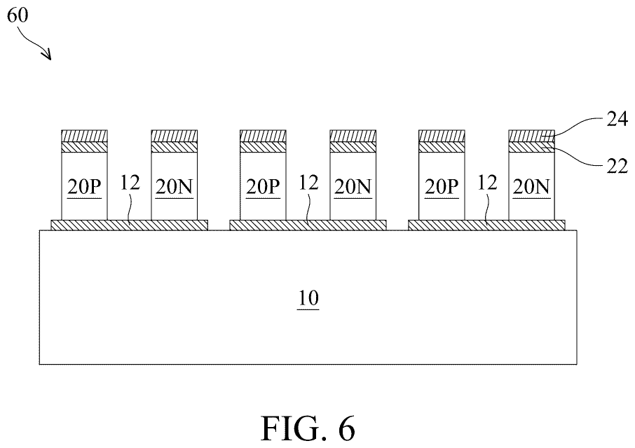

In FIG. 6, the patterned mask 16 is removed using a suitable process, such as an ashing process or the like. In the process steps described above for FIGS. 2-6, the n-type regions 20N are deposited before the p-type regions 20P are deposited, but other process steps are possible. For example, in other embodiments, the p-type regions 20P are deposited before the n-type regions 20N. In other embodiments, material for both the n-type regions 20N and the p-type regions 20P is deposited in the same step, and then appropriate dopants are introduced into the n-type regions 20N and/or into the p-type regions 20P. In this manner, a thermoelectric structure may be formed on the structure 10, in some embodiments.

In FIGS. 7 and 8, a metallization component 30 is bonded to the bond regions 24, in accordance with some embodiments. The metallization component 30 comprises a metallization pattern 32 formed on an upper substrate 31, in some embodiments. The upper substrate 31 may be any suitable substrate, such as a wafer, a panel, a semiconductor substrate (e.g., a silicon substrate), a dielectric substrate, a ceramic substrate, or the like. The upper substrate 31 may be formed of or comprise an insulating material. The metallization pattern 32 may be formed on the upper substrate 31 using materials and techniques similar to those described previously for the metallization pattern 12, though other materials or techniques are possible. The metallization pattern 32 may be patterned to electrically connect corresponding pairs of n-type regions 20N and p-type regions 20P after bonding (see FIG. 8).

In some embodiments, the metallization component 30 also comprises bond regions 34 formed on the metallization pattern 32. In other embodiments, the bond regions 34 are not formed. In some embodiments, each bond region 34 comprises a region (e.g. layer, pad, etc.) of conductive material that corresponds to a respective bond region 24. The bond regions 34 may be similar to the bond regions 24 described previously, and may be formed of similar materials using similar deposition techniques. For example, in some embodiments, the bond regions 34 comprise indium formed using a suitable technique.

In some embodiments, the bond regions 34 of the metallization component 30 may be physically and electrically connected to the bond regions 24 using fusion bonding, direct bonding, metal-to-metal bonding, or the like. For example, the bond regions 34 may be placed on corresponding bond regions 24. A thermal process, such as an annealing process, a reflow process, or the like, may then be performed to bond each bond region 34 to its corresponding bond region 24. Other techniques are possible. After bonding, n-type regions 20N and p-type regions 20P may be serially connected in an alternating configuration, as shown in FIG. 8. Some or all of the n-type regions 20N and the p-type regions 20P of the TE component 50 may be serially connected in this manner. In some embodiments, some sets of serial connections may be parallel to or independent from other sets of serial connections.

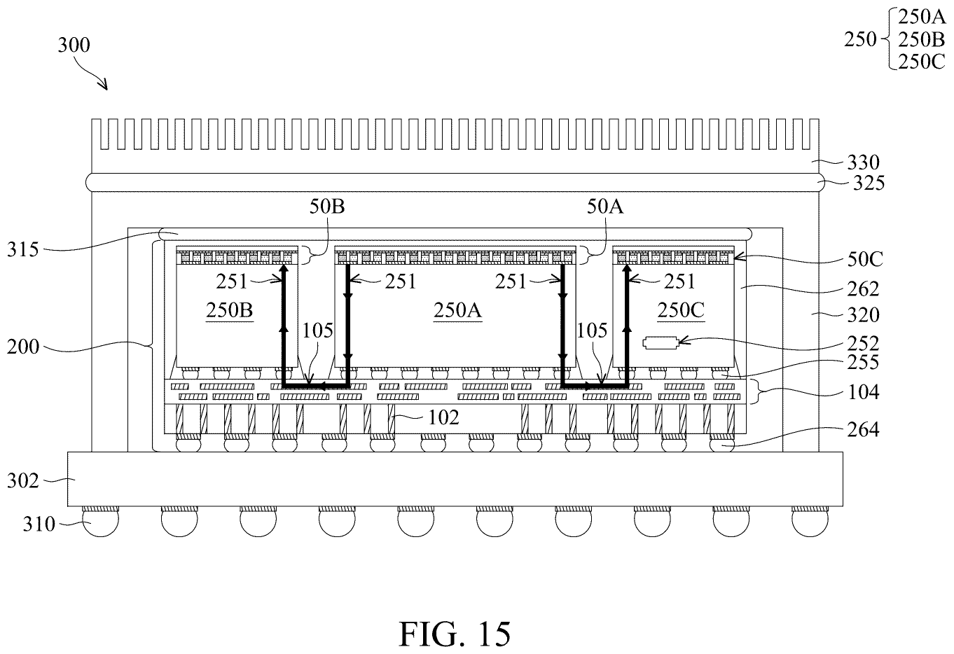

Referring to FIG. 8, after bonding, an insulating material 40 may be deposited between the structure 10 and the upper substrate 31 to protect and electrically insulate the n-type regions 20N and the p-type regions 20P, in accordance with some embodiments. The insulating material 40 may be, for example, an underfill, a dielectric material, a ceramic material, a molding compound, an encapsulant, or another suitable material. In this manner, a TE component 50 may be formed on a structure 10 to form a device 60, though other processing steps are possible. In some cases, a TE component 50 to be used only for TEG operation may be formed using different materials or process steps than a TE component 50 to be used only for TEC operation. In some embodiments, a TE component 50 may have a thickness in the range of about 20 μm to about 100 μm, though other thicknesses are possible. In this manner, a TE component 50 may be considered a “micro-TEG” (or “mTEG”) or a “micro-TEC” (or “mTEC”), in some cases. Integrating a TE component 50 with a structure 10 by forming the TE component on the structure 10, as described herein, may allow for more efficient thermal coupling between the TE component 50 and the structure 10, which can improve the efficiency of electrical power generation and/or cooling. Forming a TE component 50 on a structure 10 as described herein may also allow for the formation of smaller TE components 50 that are more easily integrated into a package (e.g., the package 300 shown in FIG. 15).

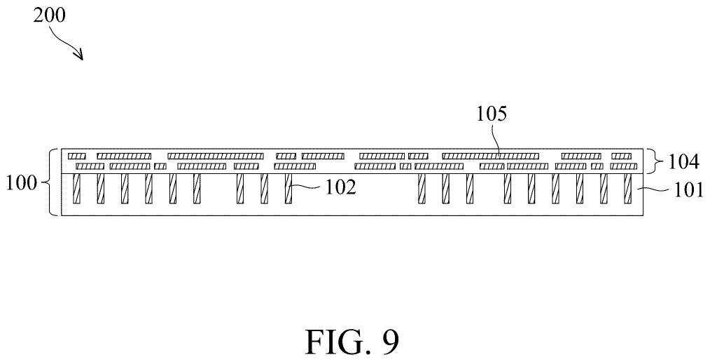

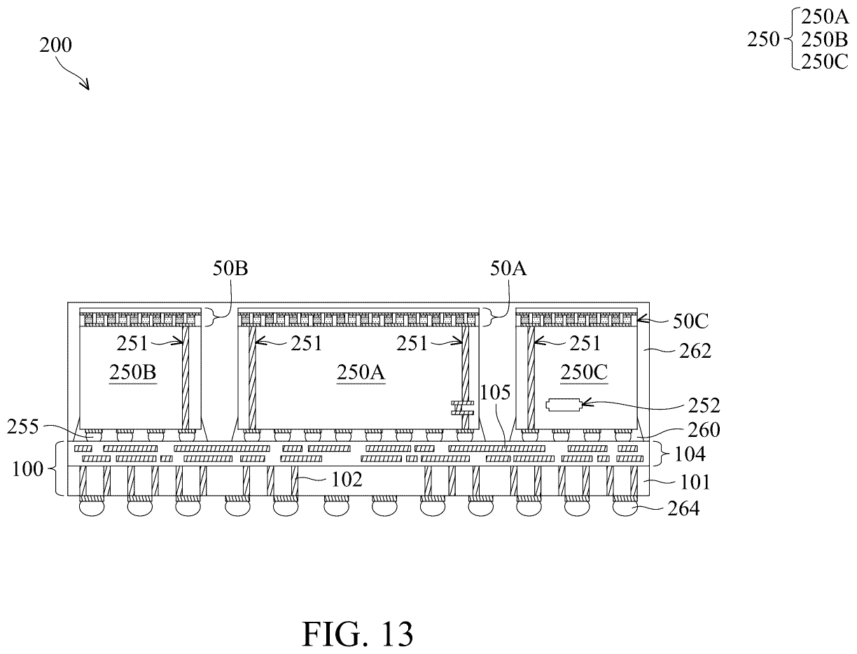

FIGS. 9 through 13 illustrate cross-sectional views of intermediate steps in the formation of a package component 200 (see FIG. 13), in accordance with some embodiments. The package component 200 comprises multiple devices 250, represented in FIGS. 9-13 by devices 250A, 250B, and 250C. Each device 250 comprises a TE component 50 that is formed at or near the top of a corresponding die 240, similar to the device 60 described for FIGS. 1-8. For example, in FIGS. 9-13, device 250A comprises a TE component 50A formed on a die 240A, device 250B comprises a TE component 50B formed on a die 240B, and device 250C comprises a TE component 50C formed on a die 240C. The TE components 50A-C may be similar to the TE component 50 described for FIGS. 1-8, and may be formed on each die 240A-C in a similar manner. For example, the structure 10 shown in FIGS. 1-8 may be a die 240A, a die 240B, or a die 240C. In an embodiment, the package component 200 is a chip-on-wafer (CoW) package, although it should be appreciated that embodiments may be applied to other three-dimensional integrated circuit (3DIC) packages.

FIG. 9 illustrates an interposer 100, in accordance with some embodiments. The interposer 100 comprises an interconnect structure 104 on a substrate 101, in accordance with some embodiments. In other embodiments, the interposer 100 may comprise an interconnect substrate, a redistribution structure, an organic core substrate, a semiconductor device, a package substrate, or the like.

The substrate 101 may be a wafer, such as a silicon wafer, in some embodiments. Other substrates, such as a silicon-on-insulator (SOI) substrate, a multi-layered substrate, or a gradient substrate may also be used. The substrate 101 may be doped (e.g., with a p-type or an n-type dopant) or undoped. In some embodiments, the semiconductor material of the substrate 101 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 101 may be a dielectric material such as silicon oxide, glass, ceramic, plastic, or any other suitable material that allows for structural support of overlying devices. In some embodiments, multiple interposers 100 may be formed on a single substrate 101 and then may be subsequently singulated into individual interposers 100 or individual package components. In some embodiments, active devices (e.g., transistors, diodes, or the like), passive devices (e.g. capacitors, resistors, or the like), integrated circuits, and/or the like may be formed in the substrate 101. The substrate 101 may be free of passive or active devices, in other embodiments.

In some embodiments, the interposer 100 comprises through vias 102 extending into the substrate 101. The through vias 102 are electrically connected to the interconnect structure 104. The through vias 102 may be formed, for example, by forming openings extending into the substrate 101. The openings may be formed using acceptable photolithography and etching techniques, such as by forming and patterning a photoresist and then performing an etching process using the patterned photoresist as an etching mask. The etching process may include, for example, a dry etching process and/or a wet etching process. A conductive material may then be formed in the openings, thereby forming the through vias 102. In some embodiments, a liner (not shown) may be deposited in the openings prior to forming the conductive material. The conductive material may comprise, for example, a metal or a metal alloy such as copper, silver, gold, tungsten, cobalt, aluminum, alloys thereof, or the like. A planarization process (e.g., a CMP process or a grinding process) may be performed to remove excess conductive material along the surface of the substrate 101 such that surfaces of the through vias 102 and the substrate 101 are level. The through vias 102 may protrude from the substrate 101 and into the interconnect structure 104, in other embodiments. Other materials or techniques are possible.

The interconnect structure 104 comprises one or more layers of conductive features 105 formed in one or more dielectric layers (not individually illustrated), in some embodiments. The conductive features 105 may comprise conductive lines, conductive vias, conductive pads, metallization patterns, redistribution layers, or the like that provide electrical interconnections and electrical routing. In some embodiments, the conductive features 105 comprise conductive pads (not illustrated) at a top surface of the interconnect structure 104. The conductive pads may be metal pads, bond pads, Under-Bump Metallizations (UBMs), or the like. In some embodiments, the interconnect structure 104 may have multiple layers of conductive features 105, but the precise number of layers of conductive features 105 may be dependent upon the design of the interconnect structure 104. The conductive features 105 may be formed using any suitable techniques such as deposition, damascene, dual damascene, or the like. The conductive features 105 may comprise a metal or a metal alloy such as copper, silver, gold, tungsten, cobalt, ruthenium, aluminum, alloys thereof, combinations thereof, or the like. Other materials are possible.

Acceptable dielectric materials for the dielectric layers of the interconnect structure 104 include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The dielectric layers may be formed using any suitable techniques. In some embodiments, the interconnect structure 104 may have multiple dielectric layers, but the precise number of dielectric layers may be dependent upon the design of the interconnect structure 104. In other embodiments, an interposer 100 may comprise local silicon interconnects (LSIs) or the like that provide additional conductive routing.

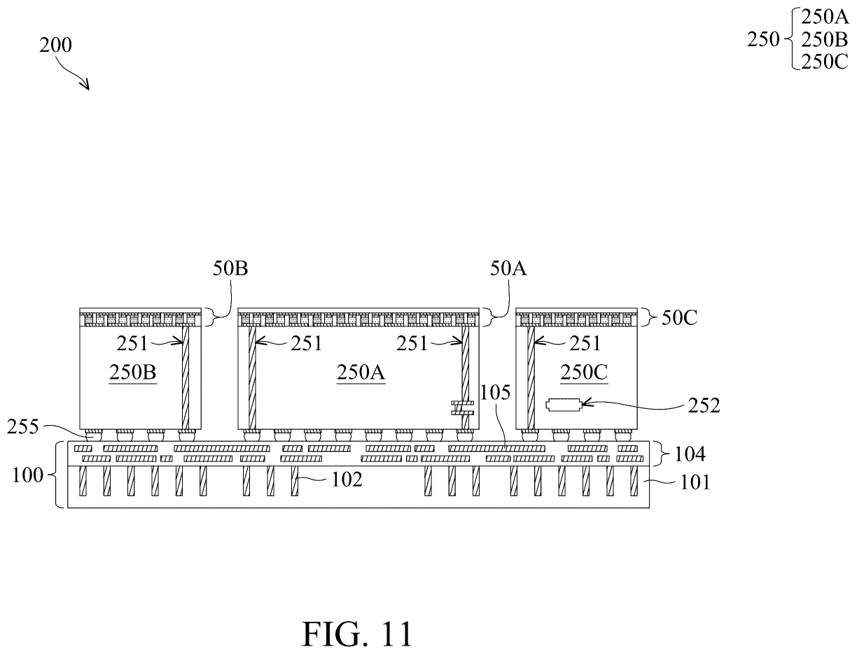

In FIGS. 10 and 11, devices 250 are bonded to the interconnect structure 104 of the interposer 100, in accordance with some embodiments. As an example, FIGS. 10-11 illustrate three devices 250 indicated as devices 250A, 250B, and 250C, but in other embodiments more or fewer devices 250 may be present. As described previously, in some embodiments, a device 250 comprises a die 240 with a TE component 50. A die 240 may include, for example, a chip, a die, a semiconductor device, an integrated circuit die, a system-on-chip (SoC) device, a system-on-integrated-circuit (SoIC) device, a package, the like, or a combination thereof. In some embodiments, a die comprises a logic die (e.g., central processing unit (CPU, xPU), graphics processing unit (GPU), a system-on-a-chip (SoC), an application processor (AP), microcontroller, etc.), a memory die (e.g., dynamic random access memory (DRAM) die, static random access memory (SRAM) die, a hybrid memory cube (HMC) die, a high bandwidth memory (HBM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a BaseBand (BB) die, a photonic integrated circuit, a photonic package, a photonic die, the like, or combinations thereof. Other types of dies 240 are possible.

FIGS. 10-11 show three devices 250A-C comprising three different types of dies 240A-C. For example, in some embodiments, the die 240A may be a logic die, the die 240B may be a memory die, and the die 240C may be a photonic die comprising a photonic component 252. The photonic component 252 may be, for example, a laser diode, a photodetector, a waveguide, an optical modulator, the like, or a combination thereof, though other photonic components are possible. In some embodiments, the dies 240 may include both high-power dies (e.g. dies that consume relatively large amounts of power) and low-power dies (e.g. dies that consume relatively small amounts of power). For example, in some embodiments, the die 240A may be a high-power die, and the dies 240B-C may be low-power dies. These are examples, and other numbers, types, arrangements, configurations, or combinations of dies 240 or devices 250 are possible.

The devices 250 may include conductive connectors 255 that are used to connect to the interposer 100, in some embodiments. The conductive connectors 255 may include, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 255 may include a conductive material such as solder, copper, aluminum, gold, nickel, silver, palladium, tin, the like, or a combination thereof. In some embodiments, the conductive connectors 255 are formed by initially forming a layer of solder through evaporation, electroplating, printing, solder transfer, ball placement, or the like. Once a layer of solder has been formed, a reflow may be performed in order to shape the material into the desired bump shapes. In another embodiment, the conductive connectors 255 include metal pillars (such as copper pillars) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In some embodiments, a TE component 50 of a device 250 is electrically connected to a conductive connector 255 of the device 250 by one or more via structures 251. The via structures 251 may comprise through-vias, conductive vias, conductive lines, and/or the like that extend through the die 240. A via structure 251 is electrically coupled to one or more TE components 50 at the top of the die 240 and is electrically coupled to one or more conductive connectors 255 at the bottom of the die 240. In this manner, the via structures 251 electrically couple the TE component(s) 50 of a device 250 to the conductive connector(s) 255 of the device 250. For example, the electrical power generated by a TE component 50 operated as a TEG may be transmitted to a conductive connector 255 by a via structure 251. As another example, an electrical current may be transmitted to a TE component 50 operated as TEC to provide cooling for the die 240. The via structures 251 shown in FIG. 10 are representative examples, and other via structures 251 are possible.

In some embodiments, the devices 250 are bonded to the interposer 100 by aligning the conductive connectors 255 with corresponding conductive features (not shown) at the top of the interconnect structure 104. For example, the conductive features of the interconnect structure 104 may be conductive pads, conductive pillars, solder bumps, or the like. The conductive connectors 255 are then placed into contact with the corresponding conductive features. Then, a reflow process may be performed to bond the conductive connectors 255 to the conductive features. In this manner, the devices 250 may be physically and electrically connected to the interconnect structure 104. In other embodiments, the devices 250 may be bonded to the interconnect structure 104 using fusion bonding, such as dielectric-to-dielectric bonding and/or metal-to-metal bonding.

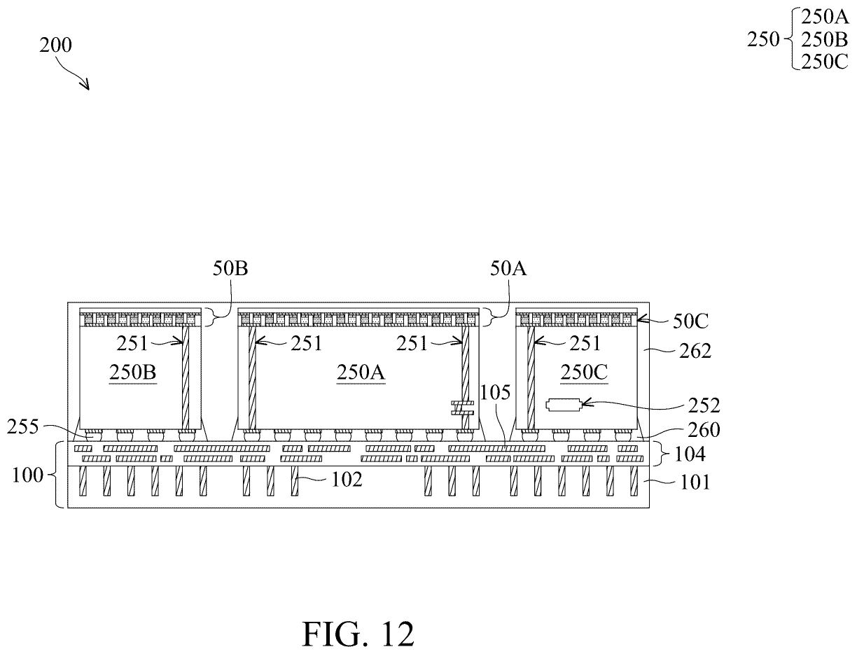

In FIG. 12, an optional underfill 260 and a molding material 262 are deposited, in accordance with some embodiments. The underfill 260 may be formed between the devices 250 and the interposer 100, and may surrounding the conductive connectors 255. The underfill may reduce stress and protect the joints resulting from the reflowing of the conductive connectors 255. The underfill may be formed by a capillary flow process after the devices 250 are attached, or may be formed by a suitable deposition method before the devices are attached. In other embodiments, an underfill 260 is not formed.

The molding material 262 is deposited over the interposer 100, over the devices 250, and between adjacent devices 250. The molding material 262 may be deposited between the devices 250 and the interposer 100 if an underfill 260 is not present. The molding material 262 may be a molding compound, an encapsulant, an epoxy, a polymer, a silicon oxide filler material, or the like. The molding material 262 may be applied by compression molding, transfer molding, deposition, or the like. The molding material 262 may be applied in liquid or semi-liquid form and then subsequently cured. In some embodiments, a planarization process, such as a CMP process or a grinding process, may be performed to remove excess portions of the molding material 262. In some embodiments, the molding material 262 covers the TE components 50 of the devices 250 after performing the planarization process, as shown in FIG. 12. In other embodiments, the planarization process exposes the devices 250, and top surfaces of the devices 250 and the molding material 262 are substantially level after performing the planarization process.

In FIG. 13, conductive connectors 264 are formed on the interposer 100, in accordance with some embodiments. In some embodiments, a planarization process (e.g., a CMP or grinding process) is performed on the substrate 101 to expose the through vias 102. Conductive features such as redistribution layers, UBMs, or the like (not illustrated) may then be formed over the substrate 101 and over the exposed through vias 102. In some embodiments, conductive connectors 264 are formed over the substrate 101 and over the exposed through vias 102 or over the conductive features (if present). In this manner, the conductive connectors 264 may be electrically connected to the through vias 102. The conductive connectors 264 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 264 may be formed of a conductive material that is reflowable, such as solder, copper, aluminum, gold, nickel, silver, palladium, tin, the like, or a combination thereof. In some embodiments, the conductive connectors 264 are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, the conductive connectors 264 comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

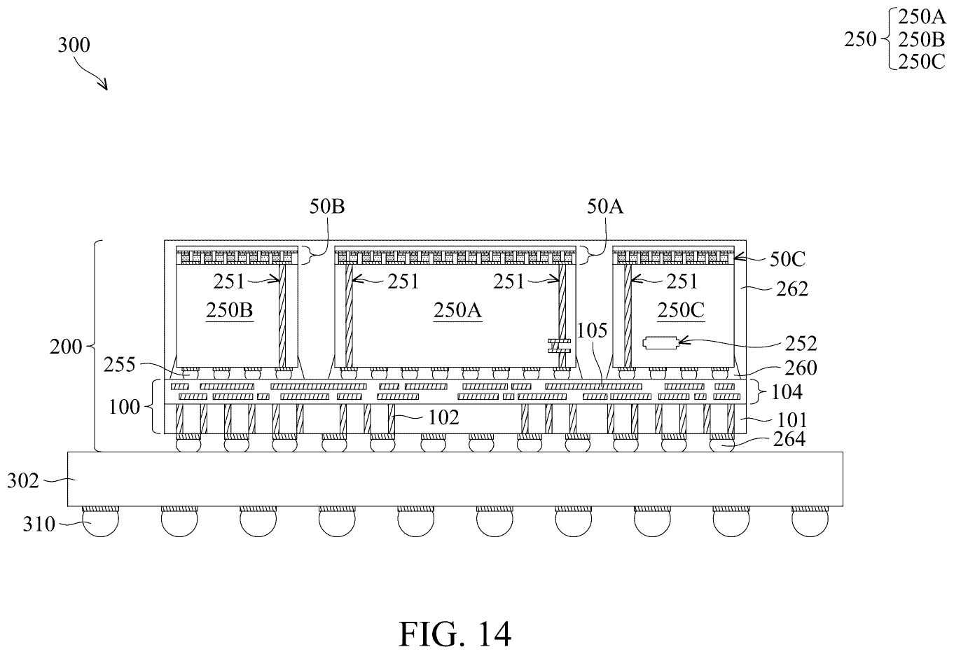

FIGS. 14 and 15 illustrate cross-sectional views of intermediate steps in the formation of a package 300, in accordance with some embodiments. FIG. 14 illustrates the attachment of a package component 200 to a package substrate 302, in accordance with some embodiments. The package component 200 may be physically and electrically connected to the package substrate 302 by the conductive connectors 264. In an embodiment, the package 300 may be a chip-on-wafer-on-substrate (CoWoS) package or the like, although it should be appreciated that embodiments may be applied to other 3DIC packages.

The package substrate 302 may be any suitable substrate or component, such as a device die, a redistribution structure, an interposer, a wafer, a semiconductor substrate, a panel, a core substrate, a printed circuit board (PCB), a motherboard, a main board, or the like. The package substrate 302 may comprise conductive features such as conductive lines, conductive vias, conductive pads, or the like to make electrical interconnections within the package substrate 302 and to make electrical connections to the package component 200 or other components attached to the package substrate 302. The package substrate 302 may or may not comprise active devices and/or passive devices. In some embodiments, conductive connectors 310 are formed on the package substrate 302, which may be similar to the conductive connectors 264 described previously.

FIG. 15 illustrates the attachment of a lid 320 and an optional thermal component 330 to form the package 300, in accordance with some embodiments. The lid 320 and the thermal component 330 can facilitate the dissipation of excess heat generated by the package component 200. The lid 320 may be formed of a thermally conductive material, such as a metal. The lid 320 may be attached to the package substrate 302 using an adhesive or the like. A thermal interface material (TIM) 315 or the like may be present between the package component 200 and the lid 320 to facilitate heat transfer between the package component 200 and the lid 320.

In some embodiments, a thermal component 330 is attached to the lid 320 to provide additional heat dissipation or cooling for the package 300. The thermal component 330 may comprise, for example, a heat sink (as shown in FIG. 15), a heat pipe, a vapor chamber, a liquid cooling system, a forced air cooling system, a cooling fan, a heat spreader, the like, or a combination thereof. A TIM 325 may be present between the lid 320 and the thermal component 330 to facilitate heat transfer between the lid 320 and the thermal component 330. In some cases, the TIM 325 is an adhesive material that attaches the thermal component 330 to the lid 320. In other embodiments, the thermal component 330 is bonded directly to the lid 320, or is part of the lid 320. In other embodiments, a thermal component 330 is not present or more than one thermal component 330 is attached to the lid 320.

In some embodiments, one TE component 50 of the package component 200 may be operated as a thermoelectric generator (TEG) that provides electrical power to another TE component 50 of the package component 200 that is operated as a thermoelectric cooler (TEC). In this manner, the excess heat generated from one device 250 may be utilized to facilitate cooling of another device 250, which can increase the thermal management efficiency, improve thermal stability, or reduce energy consumption of the package component 200 or of the package 300.

As an example, FIG. 15 shows arrowed lines to represent paths of electrical power that is transmitted from the TE component 50A operated as a TEG to the TE components 50B and 50C operated as TECs. As shown in FIG. 15, the electrical power may be transmitted within a device 250 through a via structure 51, and may be transmitted between devices 250 through the interposer 100. Referring to FIG. 15 as an example, the electrical power generated by the TE component 50A may be transmitted through the device 250A by its via structure 251 and transmitted into the interconnect structure 104 of the interposer 100 by a conductive connector 255 of the device 250A. The electrical power may then be transmitted within the interconnect structure 104 by conductive features 105 and then into the device 250C by a conductive connector 255 of the device 250C. The electrical power may then be transmitted to the TE component 50C by the via structure 251 of the device 250C, thus allowing the TE component 50C to be powered by the TE component 50A. This is an example, and other electrical paths are possible.

In some embodiments, a high-power device 250 that generates relatively more heat may have its TE component 50 operated as a TEG to provide electrical power to one or more TEC-operated TE components 50 of other devices 250. For example, with reference to FIG. 15, the device 250A may be a relatively high-power device that generates more heat than the devices 250B-C, and TE component 50A is used to generate electrical power for the TE components 50B-C. In some cases, the devices 250 having TEC-operated TE components 50 (e.g., devices 250B-C) may be devices having dies 240, modules, circuits, or components that are sensitive to temperature. For example, temperature-sensitive devices 250 may comprise a memory die (e.g., a DRAM die or the like) or may comprise photonic components (e.g., photonic component 252). Temperature-sensitive photonic components 252 may include, for example, laser diodes, waveguides, optical modulators, or the like. Other temperature-sensitive devices 250 are possible.

Temperature-sensitive devices may be sensitive to thermal cross-talk within the package 300 or may be sensitive to thermal instability within the package 300, which can cause undesired variation in operating characteristics. Accordingly, by integrating a TE component 50 into a device 250 as described herein, the TE component 50 may be operated as TEC to cool the device 250 into a desired temperature range or may be operated as a thermoelectric heater to heat the device 250 into a desired temperature range. The TE component 50 may be utilized to adjust the temperature of the device 250 in order to maintain a more stable temperature, such as maintaining the temperature of the device 250 within a desired range. In this manner, the operation of a temperature-sensitive device 250 may be made more reliable, stable, and predictable by controlling the temperature of the device 250 using its integrated TE component 50. Further, powering one TE component 50 using another TE component 50 as described herein can reduce energy consumption, improve efficiency, or improve Power Usage Effectiveness (PUE) of the package 300. In some cases, the use of TE components 50 to control device 250 temperature as described herein can be used to stabilize the device 250 at a desired temperature that is different than the working temperature of the package 300. In some embodiments, a TE component 50 may be used to cool a device 250 to a temperature lower than the temperature of its environment. As another example, if the package 300 is cooled using a cold plate, a TE component 50 may be used to heat a device 250 to a desired higher operating temperature.

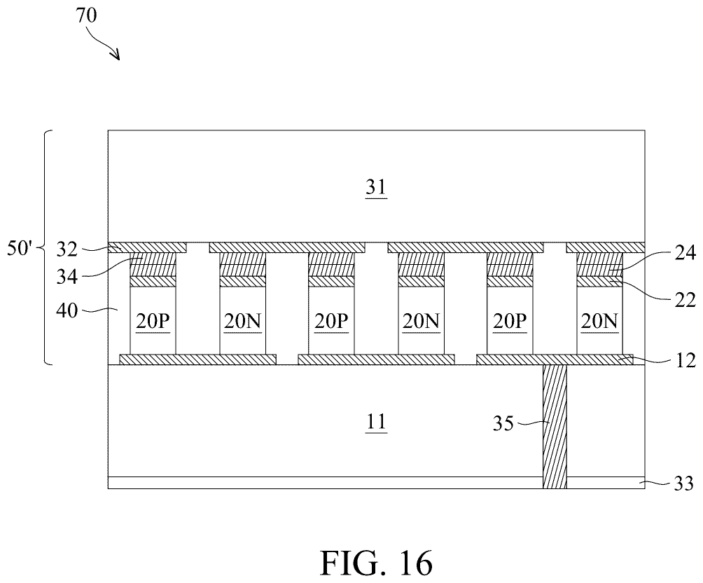

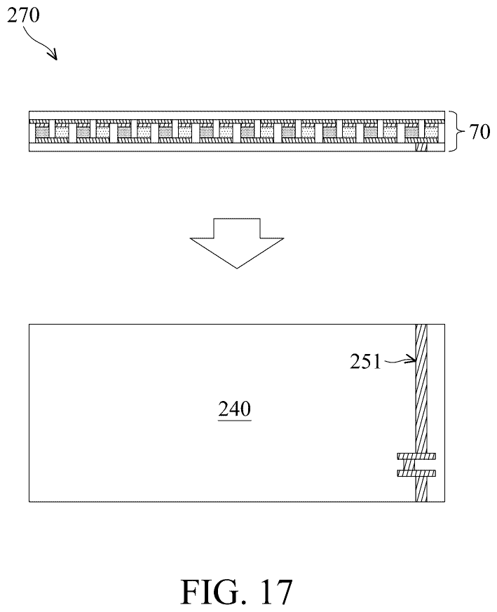

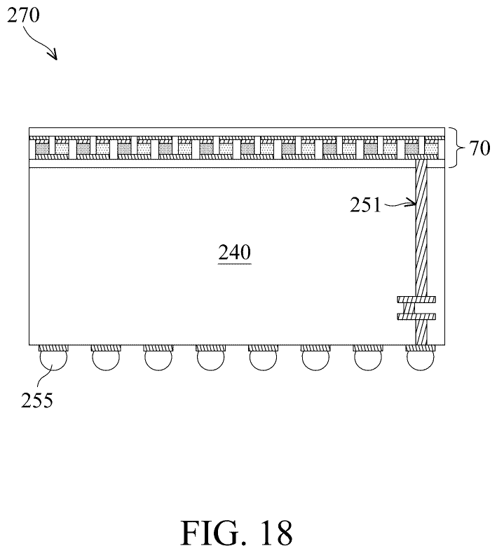

In FIGS. 1-15 described above, a TE component 50 is directly formed on a structure 10. For example, a device 250 of the package 200 comprises a TE component 50 formed on a die 240. In other embodiments, a TE component may be formed separately from the structure and then bonded to the structure. As an example, FIG. 16 illustrates a separate TE component 70 and FIGS. 17-18 illustrate intermediate steps in the formation of a device 270 comprising a TE component 70.

Referring to FIG. 16, a TE component 70 is shown, in accordance with some embodiments. The TE component 70 may be formed using some materials or techniques similar to those described previously for the TE component 50, and some similar details may not be repeated. In some embodiments, the TE component 70 comprises a TE structure 50′ formed on a bottom substrate 11. The bottom substrate 11 may comprise an insulating material, such as a semiconductor substrate (e.g., a silicon substrate), a dielectric substrate, a ceramic substrate, or the like. In some embodiments, a through via 35 extends through the bottom substrate 11 and is electrically connected to the TE structure 50′ In some embodiments, a bonding layer 33 is formed on the bottom substrate 11, which may comprise a dielectric material suitable for dielectric-to-dielectric bonding, such as silicon oxide, silicon nitride, silicon oxynitride, or the like. The through via 35 may extend through the bonding layer 33, in some embodiments. A conductive bonding pad (not shown) may be formed in the bonding layer 33 in other embodiments. In other embodiments, a bonding layer 33 is not present.

The TE structure 50′ may be similar to the TE component 50 described previously, and may be formed using similar materials and techniques. For example, the TE structure 50′ may be formed on the bottom substrate 11 in a manner similar to that of the TE component 50 being formed on the structure 10. The TE structure 50′ may comprise a plurality of n-type regions 20N and p-type regions 20P between a bottom metallization pattern 12 and a metallization pattern 32. The metallization pattern 32 may be formed on an upper substrate 31. In some embodiments, a TE component 70 may have a thickness in the range of about 20 μm to about 100 μm, though other thicknesses are possible.

In FIGS. 17-18, the TE component 70 is bonded to a die 240, in accordance with some embodiments. While FIGS. 17-18 illustrate the TE component 70 being bonded to a die 240, it should be appreciated that the TE component 70 may be bonded to any suitable structure, such as those described previously for the structure 10. In some embodiments, the TE component 70 is bonded to the die 240 using such as dielectric-to-dielectric bonding and/or metal-to-metal bonding (e.g., fusion bonding, direct bonding, hybrid bonding, or the like). For example, in some embodiments, the bonding layer 33 of the TE component 70 may be bonded to a corresponding bonding layer (not shown) on the die 240 using dielectric-to-dielectric bonding, oxide-to-oxide-bonding, or the like. In some embodiments, bonding the TE component 70 to the die 240 may electrically connect the TE component 70 to the via structure 251 of the die 240. For example, the through via 35 or other conductive feature of the TE component 70 may be bonded to the via structure 251 or other conductive feature of the die 240 by metal-to-metal bonding. In this manner, the TE component 70 may be electrically coupled to conductive connectors 255 or the like on the opposite side of the die 240. The TE component 70 may be electrically connected to multiple via structures 251 of a die 240, in some embodiments.

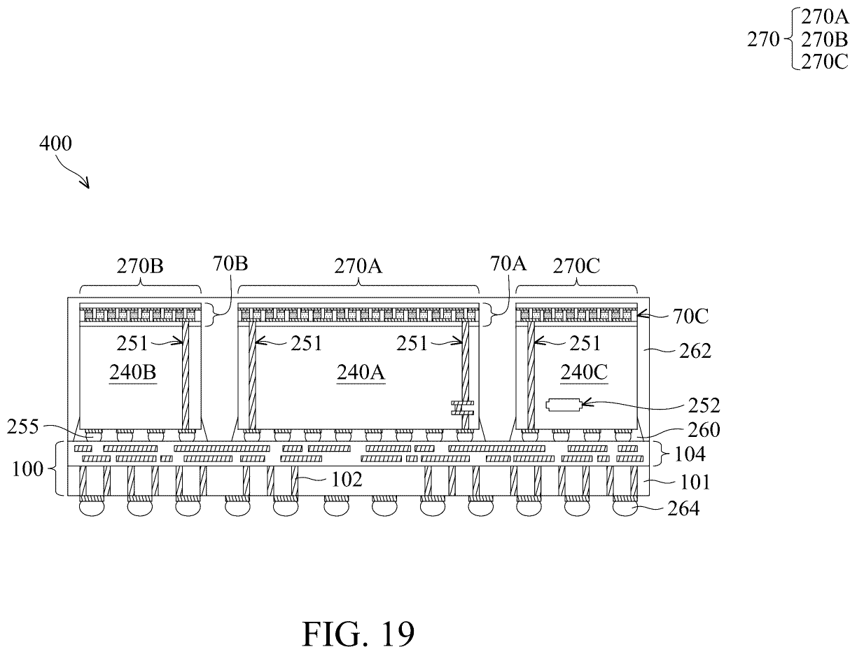

FIG. 19 illustrates a cross-sectional view of an intermediate step in the formation of a package component 400, in accordance with some embodiments. The package component 400 is similar to the package component 200 described for FIG. 13, except that devices 270 (with TE components 70) are used instead of devices 250 (with TE components 50). FIG. 19 shows a package component 400 with three devices 270A-C, but in other embodiments another number of devices 270 may be present. In other embodiments, a package component may comprise both devices 250 and devices 270. In some embodiments, the devices 270 may be covered by a molding material 262, as shown in FIG. 19, but in other embodiments, the devices 270 may be exposed.

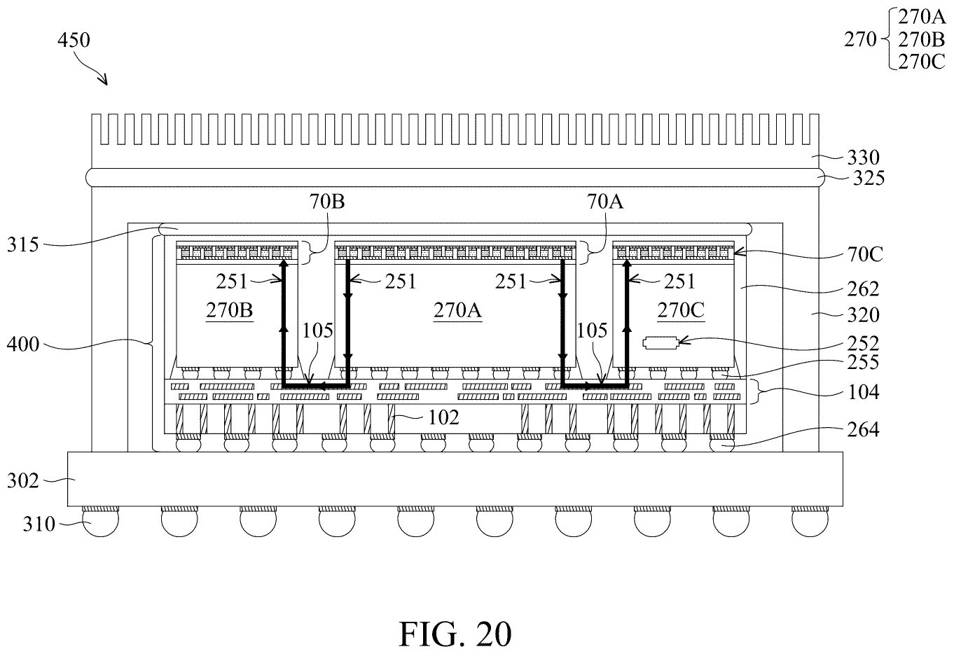

FIG. 20 illustrates a package 450, in accordance with some embodiments. The package 450 is similar to the package 300 described for FIG. 15, except that the package 450 comprises a package component 400 instead of a package component 200. The package 450 comprises a lid 320 and an optional thermal component 330, in some embodiments. A thermal interface material (TIM) 315 or the like may be present between the package component 400 and the lid 320. As an example, FIG. 19 shows arrowed lines to represent paths of electrical power that is transmitted from the TE component 70A operated as a TEG to the TE components 70B and 70C operated as TECs.

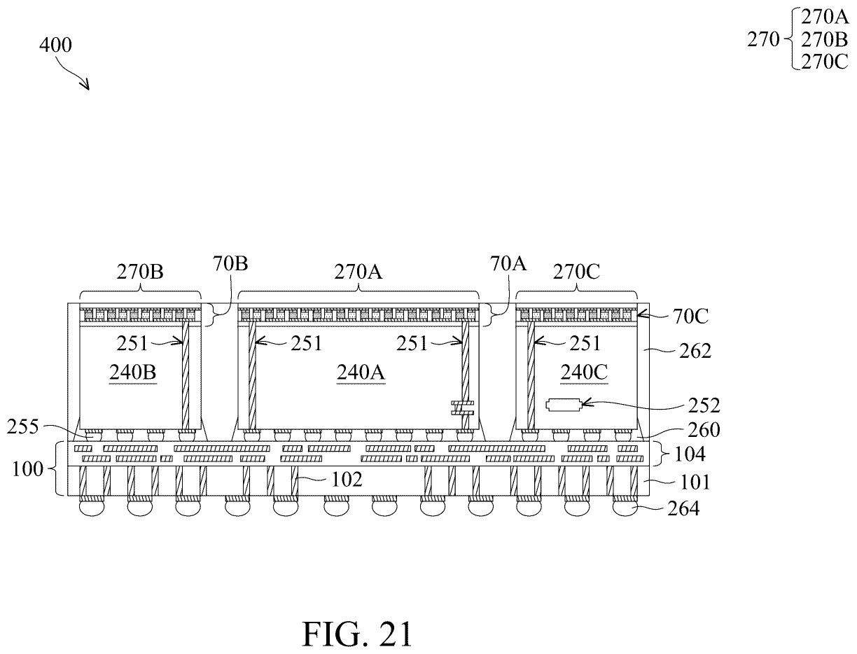

FIG. 21 illustrates a package component 400 similar to the package component 400 shown in FIG. 19, except that the TE components 70 of the devices 270 are exposed, in accordance with some embodiments. The TE components 70 may be exposed, for example, by performing a planarization process (e.g., a CMP and/or grinding process) to remove portions of molding material 262 over the devices 270. The planarization process may also remove portions of the upper substrates 31 of the TE components 70, in some cases. After performing the planarization process, top surfaces of the devices 270 and the molding material 262 may be substantially level or coplanar. In other embodiments, the molding material 262 may be thinned without exposing the devices 270.

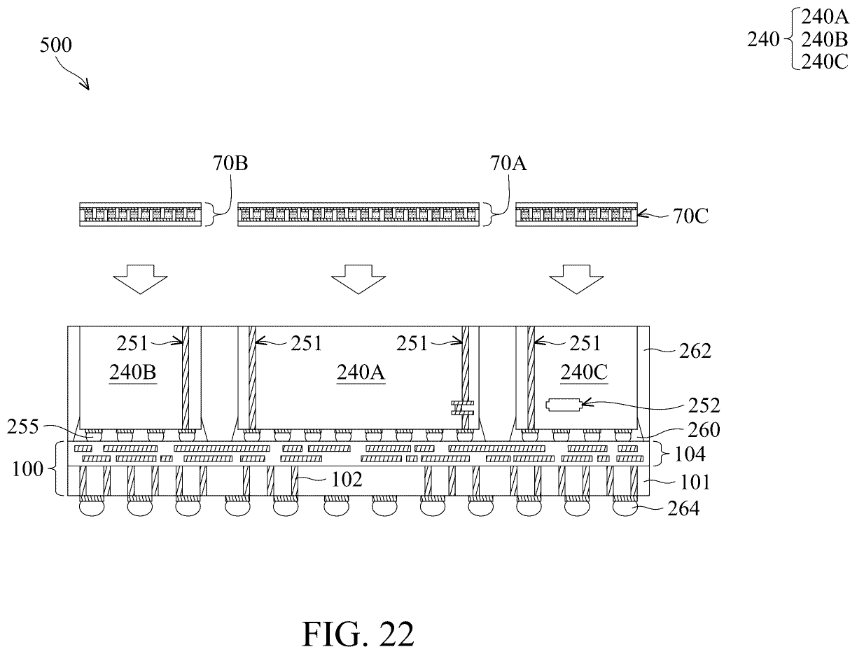

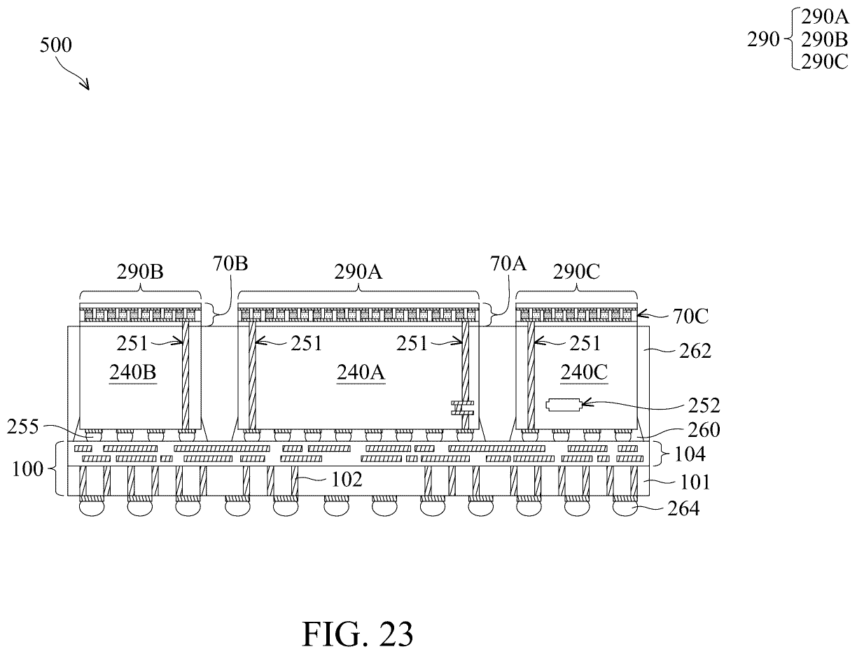

FIGS. 22-23 illustrate intermediate steps in the formation of a package component 500, in accordance with some embodiments. The package component 500 is similar to the package component 400 described for FIG. 19, except that the TE components 70 are bonded to the dies 240 after attaching the dies 240 to the interposer 100 and after depositing the molding material 262. The dies 240 may be attached to the interposer by conductive connectors 255, similar to the package component 400. An optional underfill 260 may be deposited between the dies 240 and the interposer 100. A molding material 262 may be deposited over and between the dies 240, and then a planarization process (e.g., a CMP or grinding process) may be performed to remove excess molding material 262 and expose top surfaces of the dies 240. In some embodiments, after performing the planarization process, top surfaces of the dies 240 and the molding material 262 may be substantially level or coplanar. The TE components 70 may then be bonded to the dies 240 to form devices 290, as shown in FIG. 23. The TE components 70 may be bonded using techniques similar to those described for forming the devices 270, such as dielectric-to-dielectric bonding and/or metal-to-metal bonding techniques. In this manner, a package component 500 may be formed, though other process steps are possible.

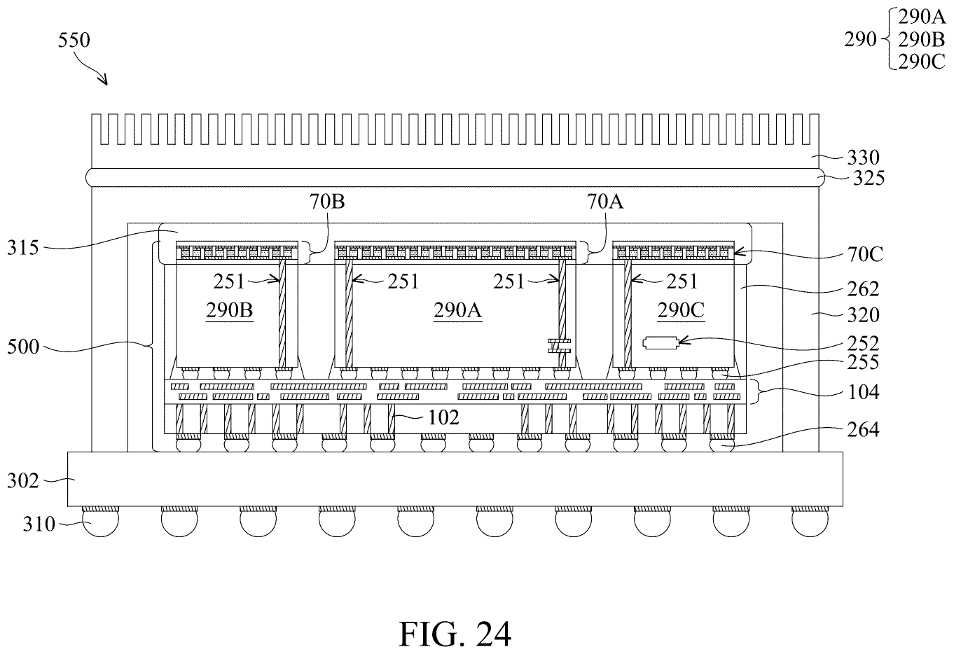

FIG. 24 illustrates a package 550, in accordance with some embodiments. The package 550 is similar to the package 450 described for FIG. 20, except that the TE components 70 of the package component 500 are not covered by molding material 262. The package 550 comprises a lid 320 and an optional thermal component 330, in some embodiments. In some embodiments, a thermal interface material (TIM) 315 or the like may be present between the package component 500 and the lid 320. Accordingly, the TIM 315 may cover top surfaces and/or sidewalls of the TE components 70, as shown in FIG. 24. By having the TIM 315 physically contact the TE components 70, heat dissipation of the package component 500 may be improved, and the efficiency of the TE components 70 may be improved.

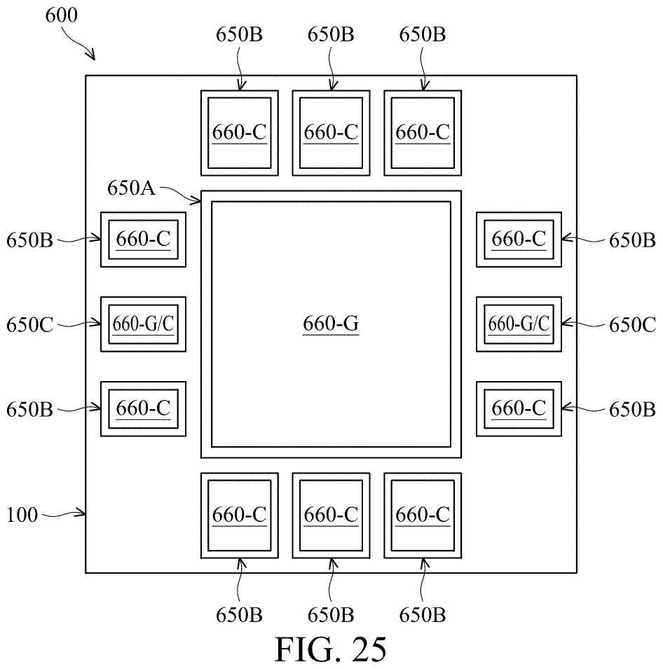

FIG. 25 illustrates a schematic plan view of a package component 600, in accordance with some embodiments. The package component 600 may be similar to other package components described herein, such as the package component 200 of FIG. 13, the package component 400 of FIG. 19, the package component 500 of FIG. 23, or variations thereof. The package component 600 comprises a plurality of devices 650 attached to an interposer 100, in accordance with some embodiments. The devices 650 may be similar to the devices 250, 270, or 290 described herein. The devices 650 shown in FIG. 25 are labeled as devices 650A-C. The devices 650B shown in FIG. 25 may or may not be the same type of device or comprise the same type of die, and the devices 650C shown in FIG. 25 may or may not be the same type of device or comprise the same type of die. For example, in some embodiments, the device 650A may comprise a logic die, the devices 650B may comprise memory dies, and the devices 650C may comprise photonic dies. This is an example, and the arrangement, number, or types of the devices 650 may be different than described above or shown in FIG. 25.

Each of the devices 650 comprises a TE component 660, which may be similar to the TE components 50 or 70 described previously. The TE components 660 operated as a thermoelectric cooler (TEC) are indicated as TE components 660-C, and TE components 660 operated as a thermoelectric generator (TEG) are indicated as TE components 660-G. In some cases, some TE components 660 may be operated as either a TEC or as a TEG, indicated as TE components 660-G/C. For example, as shown in FIG. 25, the device 650A comprises a TE component 660-G, the devices 650B comprise TE components 660-C, and the devices 650C comprise TE components 660-G/C. The arrangement, number, or types of the TE components 660 (e.g., 660-C, 660-G, and/or 660-G/C) may be different than shown in FIG. 25. The various TE components 660 may be electrically connected to the interposer 100.

In some embodiments, the TE components 660-G may be configured to provide electrical power to the TE components 660-C, similar to the other package components described previously. In some embodiments, the TE components 660-G/C may be configured to switch between TEG operation and TEC operation when desired. For example, the TE components 660-G/C may be configured to provide electrical power to the TE components 660-C or to receive electrical power (e.g., from a TE components 660-G and/or 660-G/C) to provide cooling (or heating) of the devices 650C. In this manner, the TE component(s) 660-G may be used to capture thermal energy from device(s) 650A, the TE components 660-C may be used to cool devices 650B, and the TE components 660-G/C may be used in various modes to provide thermal stabilization for the package component 600. This can result in increased efficiency, improved thermal stability, and improved thermal performance.

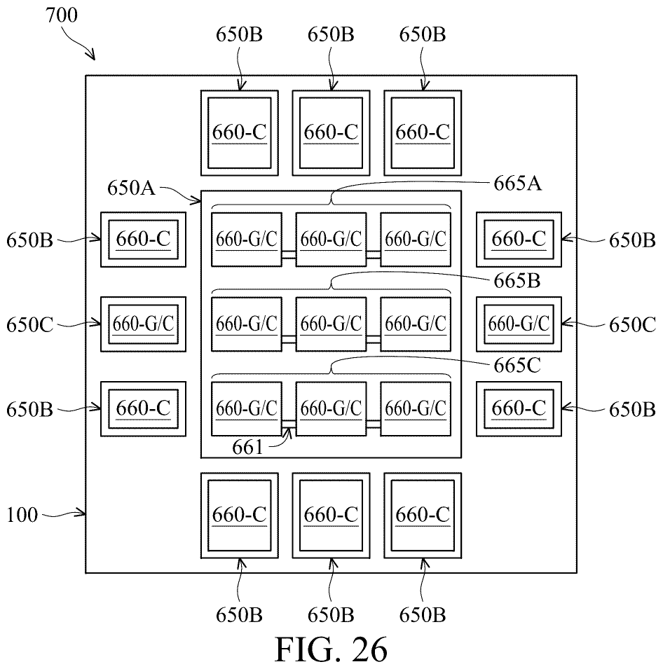

FIG. 26 illustrates a schematic plan view of a package component 700, in accordance with some embodiments. The package component 700 is similar to the package component 600 shown in FIG. 25, except that the device 650A of the package component 700 comprises a plurality of TE components 660-G/C. The TE components 660-G/C of the device 650A may be electrically coupled by interconnects 661, which may comprise conductive lines formed in or on the device 650A, conductive lines within the interposer 100, or the like. The interconnects 661 may connect the TE components 660-G/C in any suitable combination of parallel connections and/or serial connections. In some embodiments, the TE components 660-G/C are connected in a plurality of groups 665, wherein the TE components 660-G/C within each group 665 are coupled by interconnects 661. As an example, FIG. 26 shows a device 650A with three groups 665A-C comprising three TE components 660-G/C each. A different number, arrangement, or configuration of groups 665 or TE components 660-G/C are possible. In some cases, the configuration or arrangement of the groups 665 may be based on the circuit design of the device 650 or of the heat-generating characteristics of the device 650.

In some embodiments, each group 665 of TE components 660-G/C may be separately operated in a TEG mode or in a TEC mode. As an example, the group 665A may be operated in a TEG mode while the group 665C is operated in a TEC mode. Subsequently, the group 665A and the group 665C may both be operated in a TEG mode or in a TEC mode. This is an illustrative example, and any suitable combination of groups 665 operated in a TEG mode or a TEC mode is possible, and the modes of the various groups 665 may be changed as desired. In some cases, a TEG-operated group 665 may supply power to a TEC-operated group 665. The groups 665 may be switched between a TEG mode and a TEC mode in order to efficiently provide thermal management for the device 650. For example, the groups 665A-C may all be operated in a TEG mode, and one or more individual groups 665A-C may be switched to a TEC mode to cool the device 650 if the temperature of the device 250 rises to a certain temperature threshold. A group 665 may be switched between TEG mode and TEC mode based on the local heat generated near that group 665 to provide local thermal management of the device 650. These are examples, and other configurations or applications are possible.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments described herein may achieve advantages. In some cases, computing systems, photonic systems, or other packages may have multiple package components which generate different amounts of heat. Embodiments herein describe the use of thermoelectric components that are bonded to or attached to the package components to facilitate thermal management of the package. The thermoelectric (TE) components may be operated as thermoelectric generators (TEG) to generate electrical power from waste heat and/or as thermoelectric coolers (TEC) to provide cooling from received electrical power. The integrated TE components described herein have a small form factor and can be arranged and connected flexibly into thermal management systems that are application-specific. In some embodiments, some TE components operated as TEG may be used to power other TE components operated as TEC. Thus, waste heat can be converted to electricity within the same system, which can reduce the external power needed, reduce cost, and improve the efficiency of the thermal management of the system. In some embodiments, some TE components may be switched between a TEG mode and a TEC mode. The amount of electrical power generated by TEG-operated TE components and the cooling provided by TEC-operated TE components can be controlled to provide efficient heat dissipation for both high-power packages components and low-power package components. In this manner, the thermal stability of package components, such as those comprising temperature-sensitive features, may be improved. In some cases, the techniques and structures described herein can reduce lateral thermal cross-talk.

In an embodiment of the present disclosure, a method includes forming a first thermoelectric component on a first die; forming a second thermoelectric component on a second die; and connecting the first die and the second die to an interposer, wherein connecting the first die and the second die to the interposer electrically couples the first thermoelectric component and the second thermoelectric component to the interposer. In an embodiment, the first thermoelectric component is formed on the first die before the first die is connected to the interposer. In an embodiment, the first thermoelectric component is a thermoelectric generator. In an embodiment, the second thermoelectric component is a thermoelectric cooler. In an embodiment, the method includes forming a third thermoelectric component on the first die, wherein the third thermoelectric component is electrically coupled to the first thermoelectric component. In an embodiment, the method includes depositing a molding material over the first die, the second die, the first thermoelectric component, and the second thermoelectric component. In an embodiment, forming the first thermoelectric component on the first die includes depositing a conductive layer on the first die; depositing an n-type material on the conductive layer; and depositing a p-type material on the conductive layer. In an embodiment, forming the first thermoelectric component on the first die includes forming a thermoelectric structure on a substrate; and bonding the substrate to the first die.

In an embodiment of the present disclosure, a method includes forming a first thermoelectric structure on a first substrate, including depositing a first conductive layer on the first substrate; forming n-type regions on the first conductive layer; and forming p-type regions on the first conductive layer; forming a metallization component on a second substrate, including depositing a second conductive layer on the second substrate; bonding the second conductive layer to the first thermoelectric structure; and attaching the first substrate to a structure including a conductive feature, wherein the first conductive layer is electrically connected to the conductive feature. In an embodiment, the first substrate is a first semiconductor device and the structure is an interposer. In an embodiment, structure is a second semiconductor device. In an embodiment, the first substrate is a silicon substrate. In an embodiment, the method includes attaching a third semiconductor device to the structure, wherein the third semiconductor device includes a second thermoelectric structure, wherein the first thermoelectric structure is electrically connected to the second thermoelectric structure. In an embodiment, the conductive feature includes a solder bump. In an embodiment, the method includes depositing a molding material over the first thermoelectric structure.

In accordance with an embodiment of the present disclosure, a package includes a first semiconductor die attached to an interposer; a second semiconductor die attached to the interposer; a first thermoelectric component on a top surface of the first semiconductor die; and a second thermoelectric component on a top surface of the second semiconductor die, wherein the first thermoelectric component is electrically connected to the second thermoelectric component through the interposer. In an embodiment, the first thermoelectric component is a thermoelectric generator. In an embodiment, the second thermoelectric component is a thermoelectric cooler. In an embodiment, the package includes a molding material covering the first thermoelectric component and the second thermoelectric component. In an embodiment, the package includes a thermal interface material covering the first thermoelectric component and the second thermoelectric component

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
an interposer;
a first die on the interposer, wherein the first die comprises a first via;
a first thermoelectric generator on a top side of the first die, wherein the first thermoelectric generator is electrically coupled to the interposer by the first via;
a second die on the interposer, wherein the second die comprises a second via; and
a first thermoelectric cooler on a top side of the second die, wherein the first thermoelectric cooler is electrically coupled to the interposer by the second via.

2. The package of claim 1, wherein the first thermoelectric generator is electrically coupled to the first thermoelectric cooler by the interposer.

3. The package of claim 1 further comprising a heat sink extending over the first die and the second die.

4. The package of claim 1, wherein the second die comprises a photonic component.

5. The package of claim 1 further comprising a second thermoelectric generator on the top side of the first die, wherein the first thermoelectric generator is electrically coupled to the second thermoelectric generator.

6. The package of claim 1 further comprising a thermal interface material (TIM) extending over the first thermoelectric generator and the first thermoelectric cooler.

7. The package of claim 6, wherein the TIM physically contacts a sidewall of the first thermoelectric generator and a sidewall of the first thermoelectric cooler.

8. The package of claim 1, wherein a width of the first thermoelectric generator is greater than a width of the first thermoelectric cooler.

9. A package comprising:
an interconnect structure;
a first semiconductor die connected to the interconnect structure, wherein the first semiconductor die comprises a first thermoelectric component;
a second semiconductor die connected to the interconnect structure, wherein the second semiconductor die comprises a second thermoelectric component, wherein the second thermoelectric component is electrically connected to the first thermoelectric component through the interconnect structure;
a third semiconductor die connected to the interconnect structure, wherein the third semiconductor die comprises a third thermoelectric component, wherein the third thermoelectric component is electrically connected to the first thermoelectric component through the interconnect structure; and
a molding material on the interconnect structure and surrounding the first semiconductor die, the second semiconductor die, and the third semiconductor die.

10. The package of claim 9, wherein the first thermoelectric component is at the top side of the first semiconductor die.

11. The package of claim 9, wherein the first thermoelectric component is electrically connected to the interconnect structure through the first semiconductor die.

12. The package of claim 9, wherein top surfaces of the molding material, the first thermoelectric component, and the second thermoelectric component are level.

13. The package of claim 9, wherein the second thermoelectric component is operable as both a thermoelectric generator and as a thermoelectric cooler.

14. The package of claim 9, wherein the second thermoelectric component is configured to receive electrical power from the first thermoelectric component.

15. A method comprising:
forming a semiconductor device, wherein the semiconductor device comprises a via structure extending from a top side of the semiconductor device to a bottom side of the semiconductor device; and
forming a first thermoelectric component on the top side of the semiconductor device, wherein forming the first thermoelectric component comprises:
forming a first patterned metal layer on the top side of the semiconductor device, wherein the first patterned metal layer is electrically connected to the via structure;
depositing a plurality of n-type regions on the first patterned metal layer;
depositing a plurality of first metal regions on the plurality of n-type regions;
depositing a plurality of p-type regions on the first patterned metal layer;
depositing a plurality of second metal regions on the plurality of p-type regions; and
forming a second patterned metal layer on the plurality of first metal regions and the plurality of second metal regions.

16. The method of claim 15, wherein the n-type regions comprise BiTe, BiSbTe, or BiSeTe.

17. The method of claim 15 further comprising depositing a molding material around the plurality of n-type regions and the plurality of p-type regions.

18. The method of claim 15, wherein sidewalls of the semiconductor device and the first thermoelectric component are coterminous.

19. The method of claim 15, wherein the first thermoelectric component has a thickness in the range of 20 μm to 100 μm.

20. The method of claim 15 further comprising forming a second thermoelectric component on the top side of the semiconductor device, wherein the second thermoelectric component is electrically connected to the first thermoelectric component.
